(19) United States
(12) Patent Application Publication
(10) Pub. No.: US 2015/0194418 A1
(43) Pub. Date: Jul. 9, 2015

(54) ELECTROSTATIC DISCHARGE EQUALIZER

(71) Applicant: ATI TECHNOLOGIES ULC, Markham (CA)

(72) Inventors: Peter E. Bade, North York (CA); Michael C. Wong, Stouffville (CA)

(73) Assignee: ATI TECHNOLOGIES ULC, Markham (CA)

(21) Appl. No.: 14/151,084

(22) Filed: Jan. 9, 2014

(51) Int. Cl. H01L 27/02

(52) U.S. Cl. CPC H01L 27/0248

(57) ABSTRACT

An integrated circuit including an electrostatic discharge (ESD) equalizer is described. The integrated circuit may include a first ESD protection circuit coupled between a first node and a ground node of the integrated circuit and a second ESD protection circuit coupled between a second node and the ground node. The integrated circuit may also include an ESD equalizer that changes from an impedance of a path between the first node and the second node from a high impedance to a low impedance in response to electrostatic discharge (ESD) through the first node or the second node.

### BACKGROUND

1. Field of the Disclosure

The present disclosure relates generally to integrated circuits and, more particularly, to an electrostatic discharge equalizer for use in integrated circuits.

2. Description of the Related Art

Integrated circuits must be able to withstand some electrostatic discharges (ESDs). For example, machine handling of the integrated circuit during fabrication and assembly of devices that include the integrated circuit may cause electrostatic charge to build up in the integrated circuit. An ESD event may then occur if a portion of the integrated circuit, such as one or more of the external pins or balls of the integrated circuit, comes into contact with a conductive material that provides a conductive path to ground. Integrated circuits therefore typically include ESD protection circuits that provide a low impedance path that allows the current generated during an ESD event to bypass functional portions of the integrated circuit and pass to ground without damaging the functional portions of the integrated circuit.

Charge device model (CDM) testing of an integrated circuit may be used to ensure that the ESD protection circuits actually protect the integrated circuit from ESD events. For example, each internal node of the integrated circuit may be charged to ±250V and then a probe may be placed in contact with one of the external pins or balls of the integrated circuit to provide a conductive path between ground and the external pin or ball. Depending upon the initial polarity of the charge, a relatively large current (e.g. 10 Amps) then flows into or out of the integrated circuit through the external pin or ball. If the ESD protection circuit associated with the external pin or ball is functioning correctly, the current flow should not damage circuitry in the functional portions of the integrated circuit.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of an integrated circuit in accordance with some embodiments.

FIG. 2 is a block diagram of an integrated circuit including different ESD protection circuits for different portions of internal circuitry of the integrated circuit in accordance with some embodiments.

FIG. 3 is a block diagram of an integrated circuit including a level shifter between different power domains of the integrated circuit in accordance with some embodiments.

FIG. 4 is a block diagram of an integrated circuit that includes an ESD equalizer in accordance with some embodiments.

FIG. 5 is a circuit diagram of an ESD equalizer in accordance with some embodiments.

FIG. 6 is a circuit diagram of another ESD equalizer in accordance with some embodiments.

FIG. 7 is a flow diagram illustrating a method for designing and fabricating an integrated circuit device implementing at least a portion of a component of a processing system in accordance with some embodiments.

### DETAILED DESCRIPTION

Some integrated circuits may include multiple power domains that operate at different voltages and maybe interconnected by one or more intermediate circuit such as a level shifter. The intermediate circuits may be exposed to enhanced voltage drops during electrostatic discharge (ESD), as discussed below. The enhanced voltage drops increase the probability that the intermediate circuits may be damaged during an ESD event even though the multiple power domains may incorporate separate ESD protection circuits. Voltage drops across the intermediate circuits may be reduced using an ESD equalizer that detects ESD events and reduces the voltage differential across the intermediate circuits in response to detecting an ESD event. The ESD equalizer may therefore protect the intermediate circuits from damage during ESD event such as CDM testing or accidental ESD events during handling of a device including the circuits.

Conventional circuitry for protecting intermediate circuits from damaged during ESD events may introduce other problems in the integrated circuit. One approach is to reduce the voltage drop across an intermediate circuit using a pair of diodes with opposite orientations, e.g., back-to-back diodes. Forward biasing of one of the diodes during CDM testing or an ESD event limits the voltage differential across the intermediate circuit by providing a conductive path. However, diodes may be forward biased even during normal operation when there are no ESD events occurring, which may lead to incorrect operation of the integrated circuit. For example, the diodes can introduce a power-up sequence dependency in the integrated circuit. If the first power domain is powered up before the second power domain is intended to be powered up, forward biasing of one of the diodes allows the second power domain to begin powering up, and vice versa. Leakage currents through the forward-biased diode may drain power and thwart attempts to conserve power by placing one of the power domains in a low-power or power-off mode while the other power domain remains powered up. Moreover, electrical noise may be conveyed between the two power domains by the diodes, which may be problematic if either of the power domains includes circuits that are sensitive to noise, such as phase locked loops or other sensitive analog circuits.

Another approach is to use a capacitor to prevent current flow through the intermediate circuit during transient events such as CDM testing, HBM testing, or ESD events. However, the capacitor may convey electrical noise between the two power domains during normal operation. Furthermore, a capacitor of sufficient size to prevent current flow during CDM testing or ESD events would consume an undesirably large amount of silicon area on the integrated circuit or would alternatively need to be implemented as an external capacitor in the integrated circuit package. Yet another approach is to fabricate the ESD protection circuits for the power domains using more and/or larger transistors as the conduction device between power and ground. Reducing the voltage drop (Vp) in this way may also reduce the enhanced voltage drop (˜2Vp) across the intermediate circuits. However, the reduction in the voltage drop does not scale linearly with increasing number or size of the transistors in the ESD protection circuit and the marginal decrease in the voltage drop for each incremental increase in the number or size of transistors becomes smaller as the number or size of transistors increases.

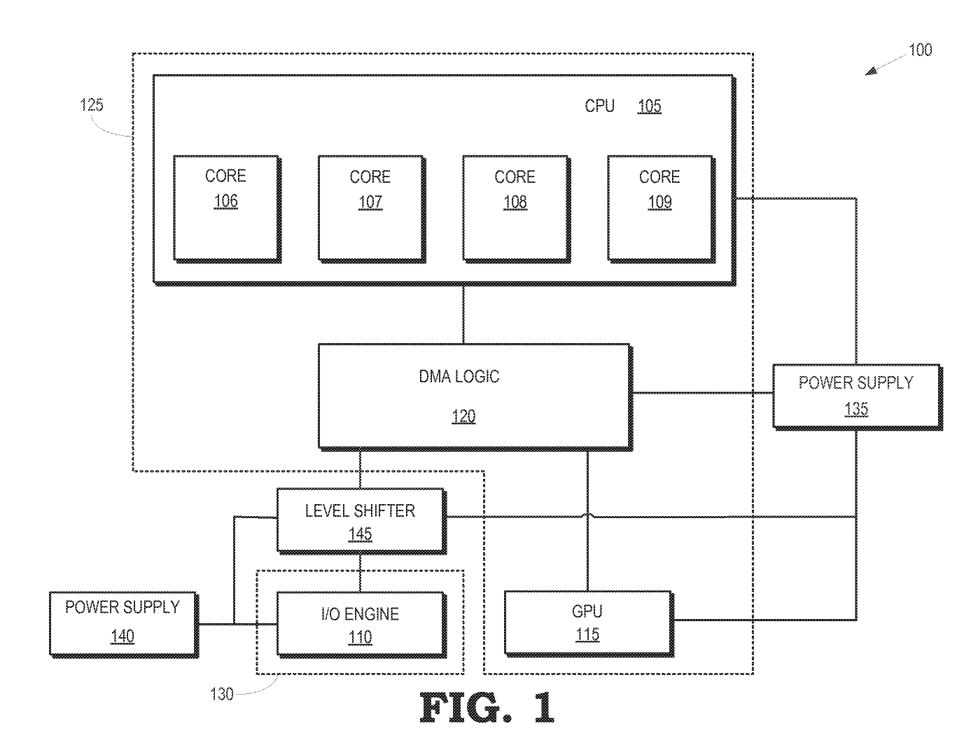

FIGS. 1-5 depict embodiments of an ESD equalizer that equalizes the voltage between two nodes in an integrated circuit in response to detecting an ESD event involving the two nodes. The ESD equalizer provides a high impedance path between the two nodes during normal operation and consequently reduces or eliminates the drawbacks of other approaches to protecting intermediate circuits during CDM testing or other ESD events. Some embodiments of the ESD equalizer may detect ESD events and equalize the voltage between a first node that is coupled to a first power supply node (VDD1) and a second node that is coupled to a second power supply node (VDD2) in response to detecting the ESD event. The two nodes may therefore be referred to herein as power supply node VDD1 and power supply node VDD2. However, the nodes may also be referred to as first and second nodes, power supply nodes, VDD nodes, or simply as VDD1 and VDD2. The voltage applied to the power supply nodes VDD1 and VDD2 may also be referred to as VDD1 and VDD2, respectively. The ESD equalizer may include a first circuit that detects an ESD event and provides a signal to a second circuit that provides a low impedance path between the power supply nodes VDD1 and VDD2 in response to the signal provided by the first circuit. The ESD equalizer may thereby reduce or eliminate leakage currents during power up or normal operation, as well as crosstalk between the power supply nodes VDD1 and VDD2, because the low impedance path is not present during normal power ramp up or normal operation. The low impedance path between the power supply nodes VDD1 and VDD2 is only present during an ESD event such as ESD events that may be intentionally created during CDM testing.

Some embodiments of the first circuit may include a first pair of capacitors that divide the voltage drop between the power supply nodes VDD1 and VDD2 to provide a voltage signal to a gate of an NMOS transistor in the second circuit. A source of the NMOS transistor may be connected to the power supply node VDD1 and a drain of the NMOS transistor may be connected to the power supply node VDD2. During power ramp up, the NMOS resistor remains turned off because its gate is connected to 0V (ground) and so the NMOS transistor does not provide a low impedance path. However, during CDM testing or an ESD event, when the power supply node VDD1 is at a lower voltage than the power supply node VDD2, e.g. VDD1=0V and VDD2=2Vp for precharging to +250V and grounding VDD1 or VDD1=−2Vp and VDD2=0 for precharging to −250Vp and grounding VDD2, the gate voltage is higher than the source voltage and lower than the drain voltage. Consequently, the NMOS transistor turns on and provides a low impedance path between the power supply nodes VDD1 and VDD2.

Some embodiments of the first circuit can also include a second pair of capacitors that divide voltages at the power supply nodes VDD1 and VDD2 and a pair of transistors that are cross-coupled to the power supply nodes VDD1 and VDD2. For example, the pair of transistors may be a first PMOS transistor and a second PMOS transistor. The second pair of capacitors and the first and second PMOS transistors operate to provide a voltage signal to a gate of a third PMOS transistor in the second circuit. A source of the third PMOS transistor is connected to the power supply node VDD2 and a drain of the third PMOS transistor is connected to the power supply node VDD1. The voltage signal supplied to the gate of the third PMOS transistor during power ramp up keeps the third PMOS transistor turned off because the gate voltage remains higher than or equal to the voltage at the source. However, during CDM testing or an ESD event, when the power supply node VDD1 is at a higher voltage than the power supply node VDD2, e.g. VDD1=2Vp and VDD2=0 for precharging to +250V and grounding VDD2 or VDD1=0 and VDD2=−2Vp for precharging to −250Vp and grounding VDD1, the gate voltage is lower than the source voltage and higher than the drain voltage. Consequently, the third PMOS transistor turns on and provides a low impedance path between the power supply nodes VDD1 and VDD2.

FIG. 1 is a block diagram of an integrated circuit 100 in accordance with some embodiments. The integrated circuit 100 includes a central processing unit (CPU) 105 for executing instructions. Some embodiments of the CPU 105 include multiple processor cores 106-109 that can independently execute instructions concurrently or in parallel. The CPU 105 shown in FIG. 1 includes four processor cores 106-109. However, persons of ordinary skill in the art having benefit of the present disclosure should appreciate that the number of processor cores in the CPU 105 is a matter of design choice. Some embodiments of the CPU 105 may include more or fewer than the four processor cores 106-109 shown in FIG. 1.

The integrated circuit 100 includes an input/output engine 110 for handling input or output operations associated with elements of the processing system such as keyboards, mice, printers, external disks, and the like. A graphics processing unit (GPU) 115 is also included in the integrated circuit 100 for creating visual images intended for output to a display. Some embodiments of the GPU 115 may include multiple cores and/or cache elements that are not shown in FIG. 1 in the interest of clarity.

The integrated circuit 100 shown in FIG. 1 also includes direct memory access (DMA) logic 120 for generating addresses and initiating memory read or write cycles. The CPU 105 may initiate transfers between memory elements in the integrated circuit 100 such as the DRAM memory (not shown) and/or other entities connected to the DMA logic 120 including the CPU 105, the I/O engine 110 and the GPU 115. Some embodiments of the DMA logic 120 may also be used for memory-to-memory data transfer or transferring data between the cores 106-109. The CPU 105 can perform other operations concurrently with the data transfers being performed by the DMA logic 120 which may provide an interrupt to the CPU 105 to indicate that the transfer is complete.

Some embodiments of the integrated circuit 100 may be divided up into multiple power domains 125, 130. For example, a first power domain 125 may include the CPU 105, the GPU 115, and the DMA logic 120. A second power domain 130 may include the I/O engine 110. The first and second power domains 125, 130 may operate at different power supply voltages and so they may be connected to different power supplies 135, 140. For example, the power supply 135 may provide power to the first power domain 125 at a supply voltage of VDD1=1.0 V and the power supply 140 may provide power to the second power domain 130 at a supply voltage of VDD2=1.8 V. Persons of ordinary skill in the art should appreciate that some embodiments of the integrated circuit 100 may be divided into different numbers of power domains that include different logical entities and operate using different power supply voltages.

A level shifter 145 may be used to convert or translate signals generated in the first power domain 125 for communication to the second power domain 130, and vice versa. For example, the level shifter 145 may be used to convert logic-high signals of 1.0 V to logic-high signals of 1.8 V when data signals are transmitted from the first power domain 125 to the second power domain 130. The level shifter may also be used to convert logic-high signals of 1.8 V to logic-high signals of 1.0 V when data signals are transmitted from the second power domain 130 to the first power domain 125. The level shifter 145 may therefore be connected to both power supplies 135, 140 so that it has access to both reference voltages. Other circuitry (not shown) may also be coupled to the power supply nodes VDD1 and VDD2 associated with both power supplies 135, 140.

The integrated circuit 100 may experience ESD events during CDM testing or when electrostatic charge builds up at one or more nodes within the integrated circuit 100 and subsequently discharges when contact with an external conductor provides a path to ground for the electrostatic charge. As discussed herein, the integrated circuit 100 may be damaged by electrostatic discharge (ESD). As used herein, the term “electrostatic discharge” will be understood to refer to the sudden transfer of electrostatic charge between bodies or surfaces at different electrostatic potentials. An ESD event may occur when a device such as an integrated circuit acquires charge through triboelectric (e.g., frictional) or electrostatic induction processes and then touches a grounded object or surface. ESD events may be generated intentionally, e.g., during CDM testing, or may be unintentional, e.g., when electrostatic charge builds upon an integrated circuit during assembly.

Circuitry that is coupled to both the first and second domains 125, 130 may be especially vulnerable to damage from ESD. Separate ESD protection circuits (not shown in FIG. 1) may be provided for the different power supplies 135, 140 associated with the different power domains 125, 130. However, the different ESD protection circuits may generate enhanced voltage drops across circuitry such as level shifters that are coupled to power supply nodes VDD1 and VDD2 associated with the different power domains 125, 130. For example, the internal impedance of the ESD protection circuits creates a voltage drop (Vp) across the ESD protection circuit when current flows through the ESD protection circuit during CDM testing or an ESD event. The voltage drop (Vp) across the ESD protection circuits for the different power domains may lead to an enhanced voltage drop (˜2Vp) across circuits such as the level shifter 145 that are connected to both the power supply nodes VDD1 and VDD2. The enhanced voltage drop may exceed the maximum safe voltage of circuits that are coupled to both power domains 125, 130. These circuits may therefore be damaged during CDM testing or an ESD event, despite the presence of the ESD protection circuits. The integrated circuit 100 may therefore include ESD protection circuits and, in some embodiments, separate ESD protection circuits may be provided for the first and second power domains 125, 130.

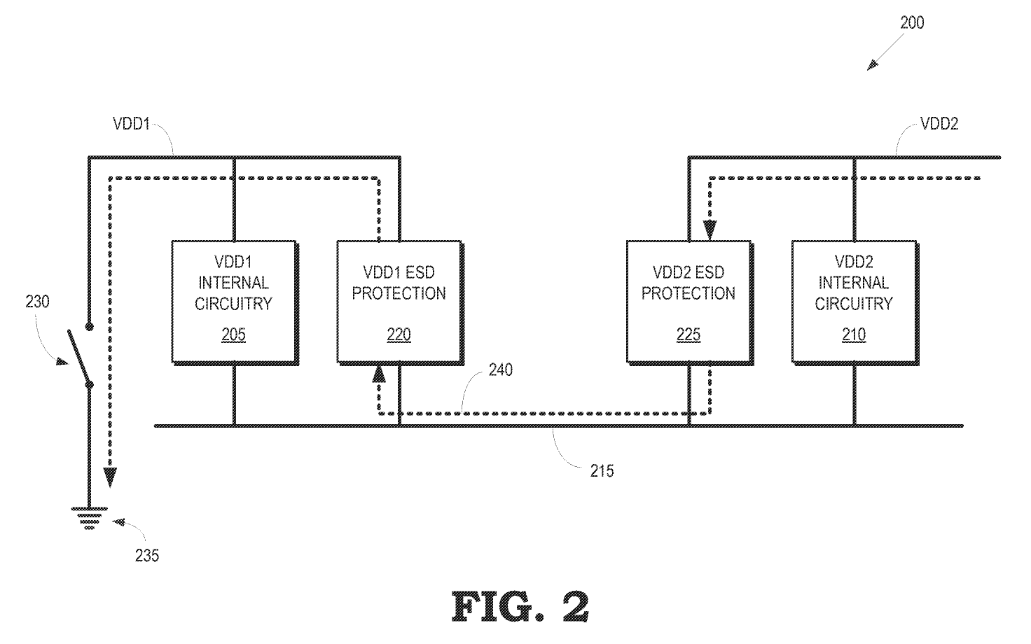

FIG. 2 is a block diagram of an integrated circuit 200 including different ESD protection circuits for different portions of internal circuitry of the integrated circuit 200 in accordance with some embodiments. The integrated circuit 200 shown in FIG. 2 includes internal circuitry that is separated into two power domains. The VDD1 internal circuitry 205 is connected to a power supply node VDD1 to supply power at a first voltage. Some embodiments of the VDD1 internal circuitry 205 may include entities in the first power domain 125 shown in FIG. 1. The VDD2 internal circuitry 210 is connected to a power supply node VDD2 to supply power at a second voltage that is different than the first voltage. Some embodiments of the VDD2 internal circuitry 210 may include entities in the second power domain 130 shown in FIG. 1. The VDD1 internal circuitry 205 and the VDD2 internal circuitry 210 are also coupled to integrated circuit (IC) ground 215. The VDD1 internal circuitry 205 is protected from ESD events by VDD1 ESD protection 220 and the VDD2 internal circuitry 210 is protected from ESD events by VDD2 ESD protection 225.

An ESD event may occur when the switch 230 is closed to provide a low impedance path from the power supply node VDD1 to earth ground 235. In some embodiments, a low impedance path may have an impedance of less than 1Ω and a high impedance path may have an impedance larger than 100 kΩ. Embodiments of the switch 230 may represent any structure that may be in an open or high impedance state during normal operation of the integrated circuit 200 and may be in a closed state to provide a low impedance path to earth ground 235 during other operational modes or circumstances. For example, the switch 230 may represent a pogo probe of a testing device that conforms to the JEDEC Standard for CDM testing (JESD22-C101E, December 2009). In that case, the switch 230 may be closed when the pogo probe contacts an external pin or ball that is conductively connected to the power supply node VDD1. For another example, the switch 230 may represent a conductor in the environment. The switch 230 may therefore be closed when the conductor in the environment of the integrated circuit 200 contacts an external pin or ball that is conductively connected to the power supply node VDD1 and provides a path to earth ground 235, e.g., during handling or processing of the integrated circuit 200. During an ESD event, the VDD1 ESD protection 220 and the VDD2 ESD protection 225 provide conductive, low impedance paths for current to pass through the integrated circuit 200 without damaging the VDD1 internal circuitry 205 or the VDD2 internal circuitry 210, as indicated by the dashed arrow 240.

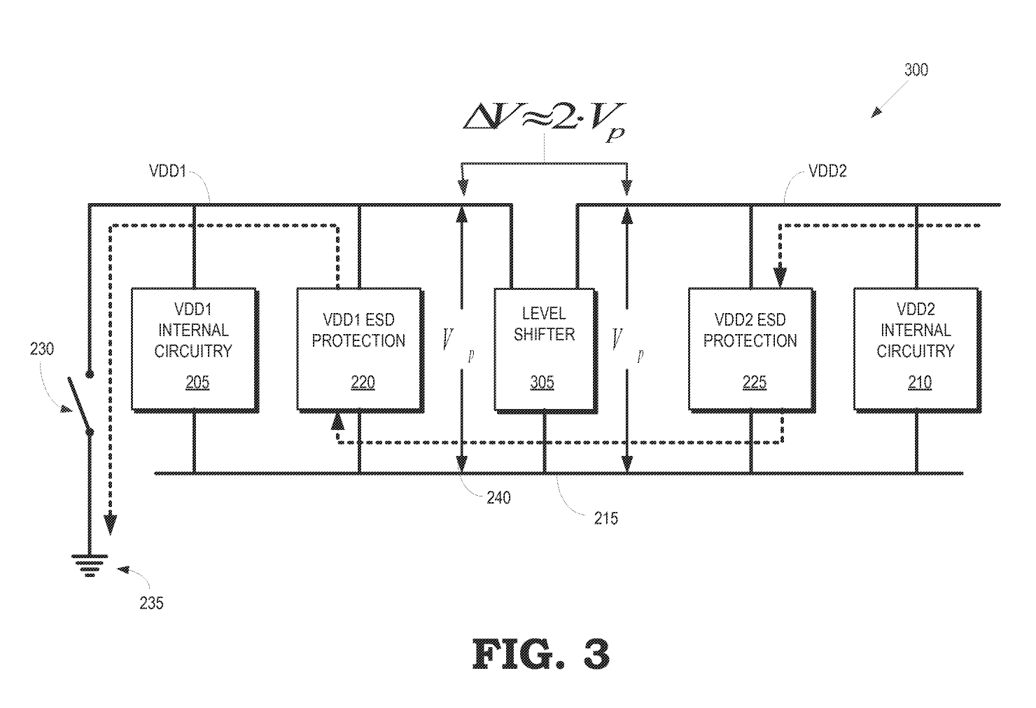

FIG. 3 is a block diagram of an integrated circuit 300 including a level shifter 305 between different power domains of the integrated circuit 300 in accordance with some embodiments. The integrated circuit 300 shown in FIG. 3 includes VDD1 internal circuitry 205, VDD2 internal circuitry 210, VDD1 ESD protection 220, and VDD2 ESD protection 225, as shown in FIG. 2. The integrated circuit 300 differs from the integrated circuit 200 shown in FIG. 2 has additional circuitry is included between the two power domains. Some embodiments of the integrated circuit 300 include a level shifter 305 such as the level shifter 145 shown in FIG. 1. The level shifter 305 is coupled to power supply nodes VDD1 and VDD2 and to IC ground 215.

An ESD event caused by closing the switch 230 to provide a low impedance path to earth ground 235 may generate an enhanced voltage drop ΔV across the level shifter 305. For example, during CDM testing, all of the nodes of the integrated circuit 300 may be charged to ±250 V and then the switch 230 may be closed to couple the power supply node VDD1 to earth ground 235. The resulting current flow along the conductive path 240 during the CDM test may result in a voltage drop of Vp across the VDD1 ESD protection 220 and a corresponding voltage drop of Vp across the VDD2 ESD protection circuit 225. Consequently, the voltage drop across the level shifter 305 from the power supply node VDD2 to the power supply node VDD1 may be approximately ΔV˜2Vp. This enhanced voltage drop may exceed the maximum safe voltage of the level shifter 305 and/or other circuits that are coupled to both power supply nodes VDD1, VDD2. These circuits may therefore be damaged during CDM testing or an ESD event, despite the presence of the ESD protection circuits 220, 225.

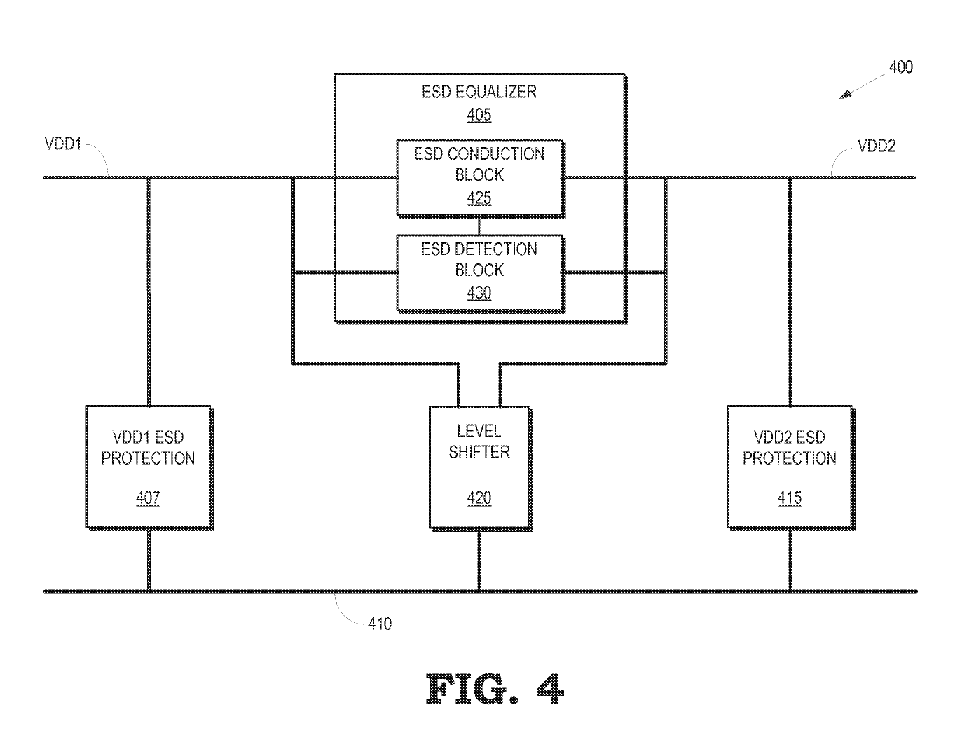

FIG. 4 is a block diagram of an integrated circuit 400 that includes an ESD equalizer 405 in accordance with some embodiments. The integrated circuit 400 includes VDD1 ESD protection 407 that is coupled between a power supply node VDD1 and IC ground 410. The VDD1 ESD protection 407 is used to provide protection for internal circuitry in a first power supply domain (not shown) of the integrated circuit 400. The integrated circuit 400 also includes VDD2 ESD protection 415 that is coupled between a power supply node VDD2 and IC ground 410. The VDD2 ESD protection 415 is used to provide protection for internal circuitry in a second power supply domain (not shown) of the integrated circuit 400. Exemplary first and second power supply domains may include the first and second power supply domains 125, 130 shown in FIG. 1. A level shifter 420 is coupled to the power supply nodes VDD1, VDD2 and IC ground 410.

The ESD equalizer 405 provides a high impedance path between the power supply nodes VDD1, VDD2 in the absence of an ESD event. For example, the ESD equalizer 405 may be a substantially open circuit when no ESD event is occurring. Consequently, no current flows between the power supply nodes VDD1 and VDD2 during normal operation of the integrated circuit 400. The ESD equalizer 405 may change from a high impedance path (e.g., approximately infinite impedance that is greater than 100 kΩ) to a low impedance path (e.g., substantially zero ohms or less than 1Ω) in response to ESD events that may occur when either of the power supply nodes VDD1 and VDD2 is coupled to earth ground. Some embodiments of the ESD equalizer 405 include an ESD detection block 425 that can generate a signal in response to detecting an ESD event caused by either of the power supply nodes VDD1 or VDD2 being coupled to earth ground. Some embodiments of the ESD equalizer 405 also include an ESD conduction block 430 that changes from a high impedance path to a low impedance path between the power supply nodes VDD1 and VDD2 in response to the signal generated by the ESD detection block 425.

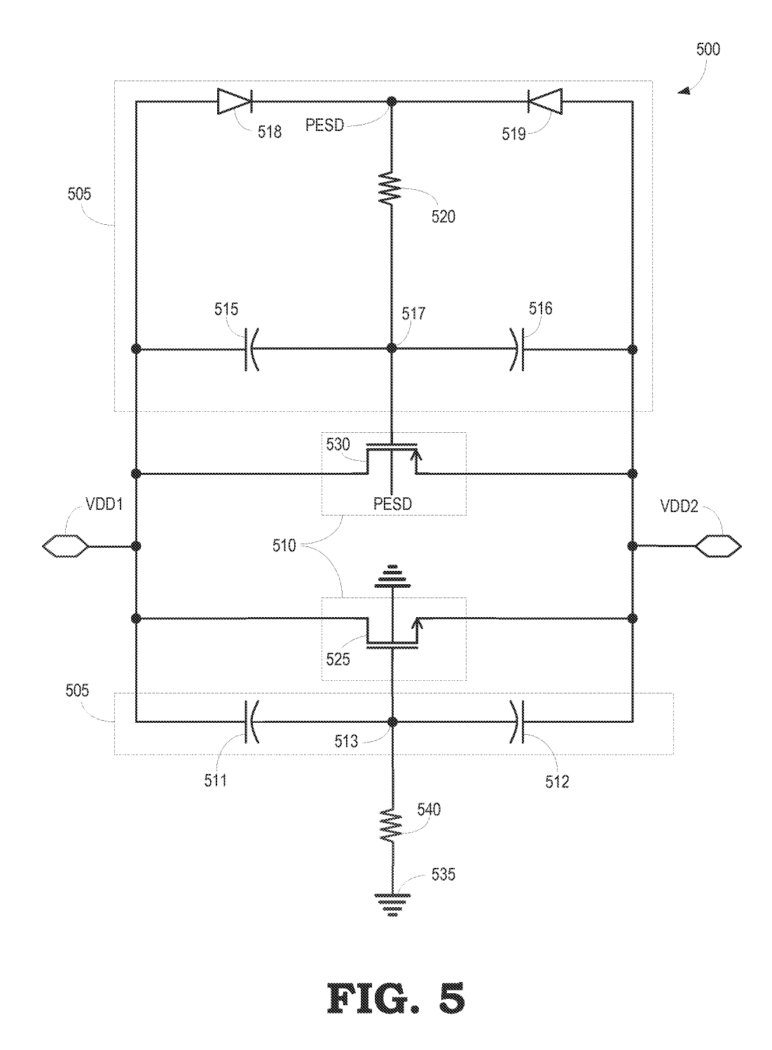

FIG. 5 is a circuit diagram of an ESD equalizer 500 in accordance with some embodiments. Some embodiments of the ESD equalizer 500 may be used as the ESD equalizer 405 shown in FIG. 4. The ESD equalizer 500 includes power supply nodes VDD1 and VDD2 that are coupled to a first circuit 505 and a second circuit 510. Some embodiments of the first circuit 505 may be used as the ESD detection block 425 shown in FIG. 4 and some embodiments of the second circuit 510 may be used as the ESD conduction block 430 shown in FIG. 4.

The first circuit 505 includes capacitors 511, 512 that are coupled in series between the power supply nodes VDD1 and VDD2 and can provide a voltage divided signal at the node 513. The first circuit also includes capacitors 515, 516 that are coupled in series between the first and second power supply nodes VDD1, VDD2 and can provide a voltage divided signal at the node 517. First and second diodes 518, 519 are coupled to the power supply nodes VDD1 and VDD2, respectively. The first and second diodes 518, 519 are also coupled to the node 517 via a resistor 520.

The second circuit 510 includes an NMOS transistor 525 coupled in series between the power supply nodes VDD1 and VDD2. A source of the NMOS transistor 525 is coupled to the power supply node VDD2, a gate of the NMOS transistor 525 is coupled to the node 513, and a drain of the NMOS transistor 525 is coupled to the power supply node VDD1. The second circuit 510 also includes a PMOS transistor 530 coupled in series between the power supply nodes VDD1 and VDD2. A source of the PMOS transistor 530 is coupled to the power supply node VDD2, a gate of the PMOS transistor 530 is coupled to the node 517, and a drain of the PMOS transistor 530 is coupled to the power supply node VDD1.

During normal operation, e.g., when the power supply nodes VDD1 and VDD2 are powered to their nominal values such as 1.0 V and 1.8 V, respectively, the NMOS transistor 525 is in an off, non-conducting high impedance state because its gate is tied to earth ground 535 by the resistor 540. The PMOS transistor 530 is in an off, non-conducting high impedance state because its gate is tied to the highest voltage at one of the power supply nodes VDD1 or VDD2. For example, once the gate of the PMOS transistor 530 has charged up, there is no voltage drop across the diodes 518, 519 because no current flows through the diodes 518, 519. Some embodiments of the PMOS transistor 530 may have their n-well tied to the highest voltage of one of the power supply nodes VDD1 or VDD2 via the node PESD to reduce or prevent leakage currents from the PMOS transistor 530 during normal operation.

During an ESD event such as a discharge triggered during CDM testing, the ESD equalizer 500 provides a conductive, low impedance path through one or more of the transistors 525, 530. The ESD events typically occur on a timescale of ˜1 ns so they can be considered alternating current (AC) events. For a signal that has a rising edge that rises on a timescale of ˜1 ns, the capacitors 511, 512, 515, 516 may be in a low impedance state because the impedance Z for a capacitor with a capacitance of C to an AC signal with a frequency of Ω is Z=1/jΩC. Some embodiments of the CDM test may charge all of the nodes in the integrated circuit, and consequently all of the nodes in the ESD equalizer 500, to the same voltage such as ±250V.

If an earth grounding probe of a CDM tester is then touched to the first power supply node VDD1 to provide a path to earth ground, at least one of the transistors 525, 530 transitions to an on, conducting low impedance state to provide a current path through the ESD equalizer 500. For example, a first voltage divider is formed between the capacitors 511, 512 and a second voltage divider is formed between the capacitors 515, 516. Voltages at the gates of the transistors 525, 530 may therefore be approximately (VDD1+VDD2)/2=Vp during the ESD event. If the nodes of the ESD equalizer 500 were initially pre-charged to +250V, the NMOS transistor 525 receives a voltage of VDD1=0V at its drain node, a voltage of Vp at its gate, and a voltage of 2Vp at its source node. The NMOS transistor 525 therefore transitions to its on, conducting, low impedance state and provides a current path through the ESD equalizer 500. If the nodes of the ESD equalizer 500 were initially pre-charged to −250V, the PMOS transistor 530 receives a voltage of VDD1=0V at its drain node, a voltage of −Vp at its gate, and a voltage of −2Vp at its source node. The PMOS transistor 530 therefore transitions to its on, conducting, low impedance state and provides a current path through the ESD equalizer 500.

If the earth grounding probe of the CDM tester is touched to the second power supply node VDD2 to provide a path to earth ground, at least one of the transistors 525, 530 transitions to an on, conducting, low impedance state to provide a current path through the ESD equalizer 500. As discussed herein, the voltage dividers provide voltages at the gates of the transistors 525, 530 of approximately (VDD1+VDD2)/2=Vp during the ESD event. If the nodes of the ESD equalizer 500 were initially pre-charged to +250V, the PMOS transistor 525 receives a voltage of VDD1=2Vp at its drain node, a voltage of Vp at its gate, and a voltage of VDD2=0V at its source node. The PMOS transistor 530 therefore transitions to a low impedance state and provides a current path through the ESD equalizer 500. If the nodes of the ESD equalizer 500 were initially pre-charged to a voltage of −250V, the NMOS transistor 525 receives a voltage of VDD1=−2Vp at its drain node, a voltage of −Vp at its gate, and a voltage of VDD2=0 at its source node. The NMOS transistor 525 therefore transitions to a low impedance state and provides a current path through the ESD equalizer 500.

Some embodiments of the ESD equalizer 500 may not include separate capacitors 511, 512, 515, 516. Instead, the first and second voltage dividers may be formed using internal capacitances of the transistors 525, 530. For example, the capacitor 511 may be replaced by an internal gate-source capacitance of the NMOS transistor 525 and the capacitor 512 may be replaced by an internal gate-drain capacitance of the NMOS transistor 525. For another example, the capacitor 515 may be replaced by an internal gate-drain capacitance of the PMOS transistor 530 and the capacitor 516 may be replaced by an internal gate-source capacitance of the PMOS transistor 530.

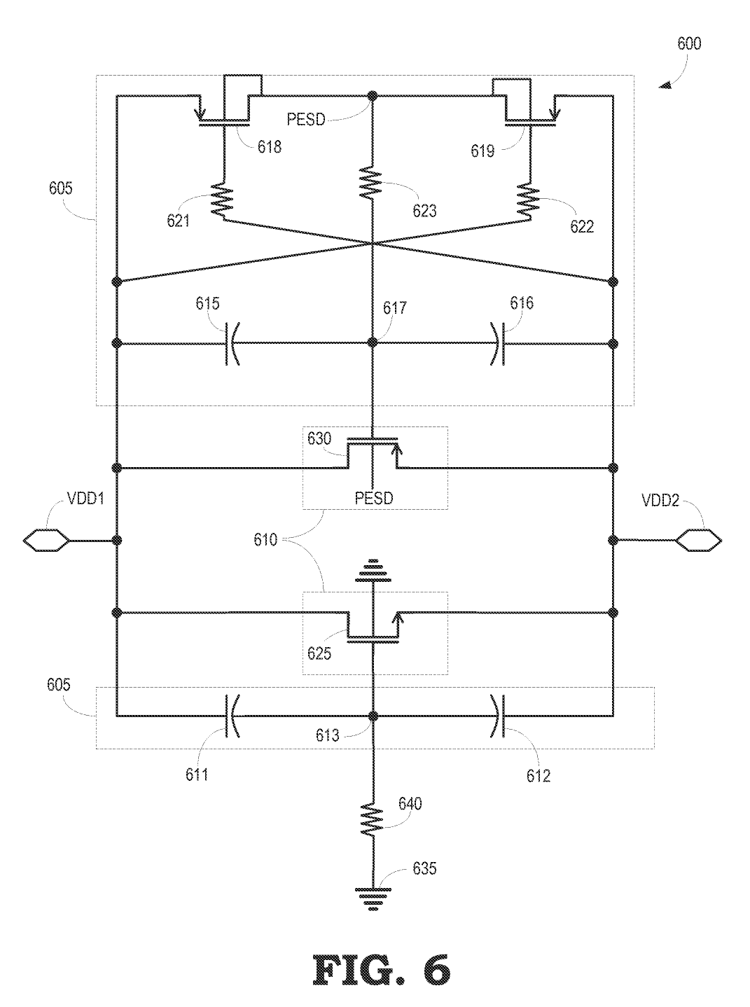

FIG. 6 is a circuit diagram of an ESD equalizer 600 in accordance with some embodiments. Some embodiments of the ESD equalizer 600 may be used as the ESD power equalizer 405 shown in FIG. 4. The ESD power equalizer 600 includes power supply nodes VDD1 and VDD2 that are coupled to a first circuit 605 and a second circuit 610. Some embodiments of the first circuit 605 may be used as the ESD detection block 425 shown in FIG. 4 and some embodiments of the second circuit 610 may be used as the ESD conduction block 430 shown in FIG. 4.

The first circuit 605 includes capacitors 611, 612 that are coupled in series between the power supply nodes VDD1 and VDD2 and can provide a voltage divided signal at the node 613. The first circuit also includes capacitors 615, 616 that are coupled in series between the power supply nodes VDD1 and VDD2 and can provide a voltage divided signal at the node 617. The source nodes of first and second PMOS transistors 618, 619 are coupled to the power supply nodes VDD1 and VDD2, respectively. The gates of the first and second PMOS transistors 618, 619 are cross-coupled to the power supply nodes VDD2 and VDD1, respectively via resistors 621, 622. The drain nodes of the first and second PMOS transistors 618, 619 are also coupled to the node 617 via a resistor 623. N-wells of the first and second PMOS transistors 618, 619 are coupled to the PESD nodes to reduce leakage currents during normal operation.

The second circuit 610 includes an NMOS transistor 625 coupled in series between the power supply nodes VDD1 and VDD2. A source of the NMOS transistor 625 is coupled to the power supply node VDD2, a gate of the NMOS transistor 625 is coupled to the node 613, and a drain of the NMOS transistor 625 is coupled to the power supply node VDD1. The second circuit 610 also includes a PMOS transistor 630 coupled in series between the power supply nodes VDD1 and VDD2. A source of the PMOS transistor 630 is coupled to the power supply node VDD2, a gate of the PMOS transistor 630 is coupled to the node 617, and a drain of the PMOS transistor 630 is coupled to the power supply node VDD1.

During power ramp up and subsequent normal operation, e.g., when the power supply nodes VDD1 and VDD2 are powered up to their nominal values such as 1.0 V and 1.8 V, respectively, both the NMOS transistor 525 and the PMOS transistor 530 remain in the off, non-conducting, high impedance state. For example, all the nodes in the ESD power equalizer 600 may initially be at 0 V. If the power supply node VDD1 ramps up first, followed by the power supply node VDD2, the voltage at the PESD node tracks the voltage at the power supply node VDD1 because the gate of the PMOS transistor 618 is tied to the power supply node VDD2, which is at 0 V. Thus, the PMOS transistor 618 is in a low impedance state. Consequently, the PMOS transistor 630 is in a high impedance state because its gate is tied to the voltage at the PESD node.

When the power supply node VDD2 powers up following ramp up of the power supply node VDD1, the voltage at the PESD node tracks the voltage at the power supply node VDD2 because the gate of the PMOS transistor 619 is tied to the power supply node VDD1 via the resistor 622. The PMOS transistor 619 is in an on, conducting, low impedance state because VDD1<VDD2. Consequently, the PMOS transistor 630 is in a non-conducting, high impedance state. The NMOS transistor 625 is also in an off, non-conducting, high impedance state throughout the ramp up process because its gate is tied to earth ground 635 via the resistor 640.

Once the power supply nodes VDD1 and VDD2 have been powered up, the ESD power equalizer 600 does not leak current because the PMOS transistor 630 remains in the off, non-conducting, high impedance state. A similar analysis shows that the ESD power equalizer 600 does not provide a low impedance path between the power supply nodes VDD1 and VDD2 in embodiments that ramp up the power supply node VDD2 before the power supply node VDD1. Some embodiments of the PMOS transistor 630 may have their n-well tied to the highest voltage of one of the power supply nodes VDD1 or VDD2 via the node PESD to reduce or prevent leakage currents from the PMOS transistor 530 during normal operation.

During an ESD event such as a discharge triggered during CDM testing, the ESD power equalizer 600 provides a low impedance path through one or more of the transistors 625, 630. As discussed herein, the capacitors 611, 612, 615, 616 may be in a low impedance state for a signal that has a rising edge that rises on a timescale of ˜1 ns. Some embodiments of the CDM test may charge all of the nodes in the integrated circuit, and consequently all of the nodes in the ESD power equalizer 600, to the same voltage such as ±250V.

If an earth grounding probe of a CDM tester is then touched to the power supply node VDD1 to provide a low impedance path to earth ground, at least one of the transistors 625, 630 transitions to an on, conducting state, low impedance to provide a current path through the ESD power equalizer 600. For example, a first voltage divider is formed between the capacitors 611, 612 and a second voltage divider is formed between the capacitors 615, 616. Voltages at the gates of the transistors 625, 630 may therefore be approximately (VDD1+VDD2)/2=Vp during the ESD event. If the nodes of the ESD power equalizer 600 were initially pre-charged to +250V, the NMOS transistor 625 receives a voltage of VDD1=0V at its drain node, a voltage of Vp at its gate, and a voltage of 2Vp at its source node. The NMOS transistor 625 therefore transitions to a conducting, low impedance state and provides a current path through the ESD power equalizer 600. If the nodes of the ESD power equalizer 600 were initially pre-charged to −250V, the PMOS transistor 630 receives a voltage of VDD1=0V at its drain node, a voltage of −Vp at its gate, and a voltage of −2Vp at its source node. The PMOS transistor 630 therefore transitions to a conducting, low impedance state and provides a current path through the ESD power equalizer 600.

If the earth grounding probe of the CDM tester is touched to the second power supply node VDD2 to provide a low impedance path to earth ground, at least one of the transistors 625, 630 transitions to an on, conducting, low impedance state to provide a current path through the ESD power equalizer 600. As discussed herein, the voltage dividers provide voltages at the gates of the transistors 625, 630 of approximately (VDD1+VDD2)/2=Vp during the ESD event. If the nodes of the ESD power equalizer 600 were initially pre-charged to +250V, the NMOS transistor 625 receives a voltage of VDD1=2Vp at its drain node, a voltage of Vp at its gate, and a voltage of VDD2=0V at its source node. The PMOS transistor 630 therefore transitions to its on, conducting, low impedance state and provides a current path through the ESD power equalizer 600. If the nodes of the ESD power equalizer 600 were initially pre-charged to a voltage of −250V, the NMOS transistor 625 receives a voltage of VDD1=−2Vp at its drain node, a voltage of −Vp at its gate, and a voltage of VDD2=0 at its source node. The NMOS transistor 625 therefore transitions to a low impedance state and provides a current path through the ESD power equalizer 600.

Some embodiments of the ESD power equalizer 600 may not include separate capacitors 611, 612, 615, 616. Instead, the first and second voltage dividers may be formed using internal capacitances of the transistors 625, 630. For example, the capacitor 611 may be replaced by an internal gate-source capacitance of the NMOS transistor 625 and the capacitor 612 may be replaced by an internal gate-drain capacitance of the NMOS transistor 625. For another example, the capacitor 615 may be replaced by an internal gate-drain capacitance of the PMOS transistor 630 and the capacitor 612 may be replaced by an internal gate-source capacitance of the PMOS transistor 630.

In some embodiments, the apparatus and techniques described above are implemented in a system comprising one or more integrated circuit (IC) devices (also referred to as integrated circuit packages or microchips), such as the ESD power equalizer described above with reference to FIGS. 1-6, electronic design automation (EDA) and computer aided design (CAD) software tools may be used in the design and fabrication of these IC devices. These design tools typically are represented as one or more software programs. The one or more software programs comprise code executable by a computer system to manipulate the computer system to operate on code representative of circuitry of one or more IC devices so as to perform at least a portion of a process to design or adapt a manufacturing system to fabricate the circuitry. This code can include instructions, data, or a combination of instructions and data. The software instructions representing a design tool or fabrication tool typically are stored in a computer readable storage medium accessible to the computing system. Likewise, the code representative of one or more phases of the design or fabrication of an IC device may be stored in and accessed from the same computer readable storage medium or a different computer readable storage medium.

A computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

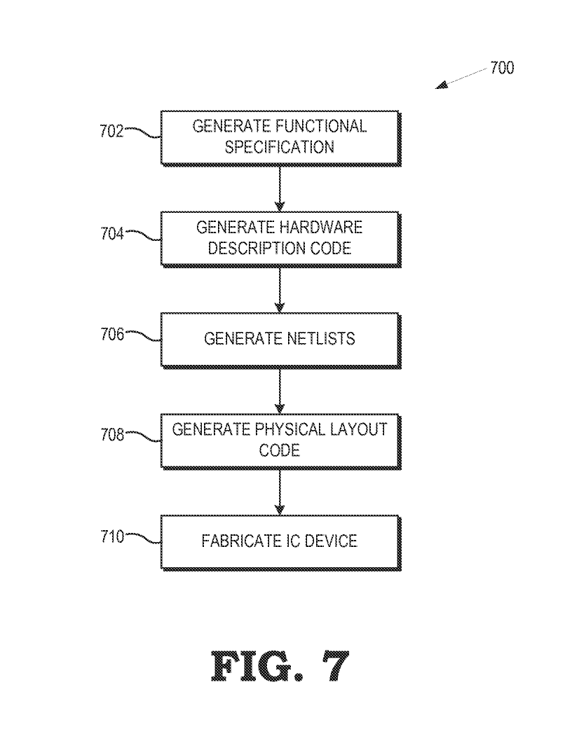

FIG. 7 is a flow diagram illustrating an example method 700 for the design and fabrication of an IC device implementing one or more aspects in accordance with some embodiments. As noted above, the code generated for each of the following processes is stored or otherwise embodied in non-transitory computer readable storage media for access and use by the corresponding design tool or fabrication tool.

At block 702 a functional specification for the IC device is generated. The functional specification (often referred to as a micro architecture specification (MAS)) may be represented by any of a variety of programming languages or modeling languages, including C, C++, SystemC, Simulink, or MATLAB.

At block 704, the functional specification is used to generate hardware description code representative of the hardware of the IC device. In some embodiments, the hardware description code is represented using at least one Hardware Description Language (HDL), which comprises any of a variety of computer languages, specification languages, or modeling languages for the formal description and design of the circuits of the IC device. The generated HDL code typically represents the operation of the circuits of the IC device, the design and organization of the circuits, and tests to verify correct operation of the IC device through simulation. Examples of HDL include Analog HDL (AHDL), Verilog HDL, SystemVerilog HDL, and VHDL. For IC devices implementing synchronized digital circuits, the hardware descriptor code may include register transfer level (RTL) code to provide an abstract representation of the operations of the synchronous digital circuits. For other types of circuitry, the hardware descriptor code may include behavior-level code to provide an abstract representation of the circuitry's operation. The HDL model represented by the hardware description code typically is subjected to one or more rounds of simulation and debugging to pass design verification.

After verifying the design represented by the hardware description code, at block 706 a synthesis tool is used to synthesize the hardware description code to generate code representing or defining an initial physical implementation of the circuitry of the IC device. In some embodiments, the synthesis tool generates one or more netlists comprising circuit device instances (e.g., gates, transistors, resistors, capacitors, inductors, diodes, etc.) and the nets, or connections, between the circuit device instances. Alternatively, all or a portion of a netlist can be generated manually without the use of a synthesis tool. As with the hardware description code, the netlists may be subjected to one or more test and verification processes before a final set of one or more netlists is generated.

Alternatively, a schematic editor tool can be used to draft a schematic of circuitry of the IC device and a schematic capture tool then may be used to capture the resulting circuit diagram and to generate one or more netlists (stored on a computer readable media) representing the components and connectivity of the circuit diagram. The captured circuit diagram may then be subjected to one or more rounds of simulation for testing and verification.

At block 708, one or more EDA tools use the netlists produced at block 706 to generate code representing the physical layout of the circuitry of the IC device. This process can include, for example, a placement tool using the netlists to determine or fix the location of each element of the circuitry of the IC device. Further, a routing tool builds on the placement process to add and route the wires needed to connect the circuit elements in accordance with the netlist(s). The resulting code represents a three-dimensional model of the IC device. The code may be represented in a database file format, such as, for example, the Graphic Database System II (GDSII) format. Data in this format typically represents geometric shapes, text labels, and other information about the circuit layout in hierarchical form.

At block 710, the physical layout code (e.g., GDSII code) is provided to a manufacturing facility, which uses the physical layout code to configure or otherwise adapt fabrication tools of the manufacturing facility (e.g., through mask works) to fabricate the IC device. That is, the physical layout code may be programmed into one or more computer systems, which may then control, in whole or part, the operation of the tools of the manufacturing facility or the manufacturing operations performed therein.

In some embodiments, certain aspects of the techniques described above may implemented by one or more processors of a processing system executing software. The software comprises one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. An integrated circuit, comprising:
a first electrostatic discharge (ESD) protection circuit coupled between a first node and a ground node of the integrated circuit and a second ESD protection circuit coupled between a second node and the ground node; and
an ESD power equalizer that changes and impedance of a path between the first node and the second node from a high impedance to a low impedance in response to electrostatic discharge (ESD) through the first node or the second node.

2. The integrated circuit of claim 1, wherein the ESD power equalizer comprises:
a first circuit to generate a signal in response to detecting electrostatic discharge (ESD) through the first node or the second node; and
a second circuit that changes the impedance of the path between the first node and the second node from the high impedance to the low impedance in response to the signal.

3. The integrated circuit of claim 2, wherein the first circuit comprises a first capacitor and a second capacitor coupled in series between the first node and the second node to provide the first signal to a third node between the first capacitor and the second capacitor.

4. The integrated circuit of claim 3, wherein the second circuit comprises a first transistor, and wherein a gate of the first transistor is coupled to the third node to receive the first signal, a source of the first transistor is coupled to the first node, and a drain of the first transistor is coupled to the second node.

5. The integrated circuit of claim 4, wherein the first transistor changes from a high impedance state to a low impedance state to provide the low impedance path in response to the first signal.

6. The integrated circuit of claim 4, wherein the first circuit comprises a third capacitor and a fourth capacitor coupled in series between the first node and the second node to provide a second signal to a fourth node between the third capacitor and the fourth capacitor.

7. The integrated circuit of claim 6, wherein the first circuit comprises a first diode and a second diode, wherein the first diode is coupled between the first node and the fourth node and the second diode is coupled between the second node and the fourth node.

8. The integrated circuit of claim 6, wherein the first circuit further comprises a second transistor and a third transistor, wherein a source of the second transistor is coupled to the first node and a source of the third transistor is coupled to the second node, and wherein a gate of the second transistor is coupled to the second node and a gate of the third transistor is coupled to the first node.

9. The integrated circuit of claim 8, wherein the second circuit comprises a fourth transistor, wherein a gate of the fourth transistor is coupled to the fourth node to receive the second signal, a source of the fourth transistor is coupled to the second node, and a drain of the fourth transistor is coupled to the first node.

10. The integrated circuit of claim 9, wherein the fourth transistor changes from a high impedance state to a low impedance state to change the impedance of the path from the high impedance to the low impedance in response to the second signal.

11. The integrated circuit of claim 9, wherein a drain of the second transistor is coupled to the fourth node and a drain of the third transistor is coupled to the fourth node.

12. The integrated circuit of claim 1, comprising a first circuit coupled in parallel with the first ESD protection circuit between the first node and the ground node and a second circuit coupled in parallel with the second ESD protection circuit between the second node and the ground node.

13. The integrated circuit of claim 12, comprising a level shifter to shift voltages of logic signals to be conveyed between the first circuit and the second circuit, the level shifter being coupled to the first node, the second node, and the ground node.

14. A method, comprising:
changing an impedance between a first node and a second node of an integrated circuit from a high impedance state to a low impedance state in response to electrostatic discharge (ESD) through at least one of the first node and the second node, wherein a first ESD protection device is coupled between the first node and a ground node of the integrated circuit, and wherein a second ESD protection device is coupled between the second node and the ground node.

15. The method of claim 14, wherein changing the impedance between the first node and the second node comprises generating, at a first circuit coupled between the first node and the second node, a signal in response to detecting the ESD through the first node or the second node.

16. The method of claim 15, wherein changing the impedance between the first node and the second node comprises changing a second circuit from a high impedance state to a low impedance state in response to the signal.

17. The method of claim 16, wherein the second circuit comprises a plurality of transistors, and wherein changing the impedance between the first node and the second node comprises turning on at least one of the transistors in response to at least one signal generated in response to detecting the ESD.

18. A non-transitory computer readable medium embodying a set of executable instructions, the set of executable instructions to manipulate a computer system to perform a portion of a process to fabricate at least part of an integrated circuit, the integrated circuit comprising:
first ESD protection circuit coupled between a first node and a ground node of the integrated circuit and a second ESD protection circuit coupled between a second node and the ground node; and
an ESD equalizer that changes an impedance of a path between the first node and the second node from a high impedance to a low impedance in response to electrostatic discharge (ESD) through the first node or the second node.

19. The non-transitory computer readable medium of claim 18, embodying a set of executable instructions to manipulate the computer system to perform a portion of a process to fabricate at least part of an integrated circuit comprising:
a first circuit to generate a signal in response to detecting electrostatic discharge (ESD) through the first node or the second node; and
a second circuit that changes the impedance of the path between the first node and the second node from a high impedance to a low impedance in response to the signal.

20. The non-transitory computer readable medium of claim 19, embodying a set of executable instructions to manipulate the computer system to perform a portion of a process to fabricate at least part of an integrated circuit comprising:
a first capacitor and a second capacitor coupled in series between the first node and the second node to provide the first signal to a third node between the first capacitor and the second capacitor;
a third capacitor and a fourth capacitor coupled in series between the first node and the second node to provide a second signal to a fourth node between the third capacitor and the fourth capacitor;
a first transistor, wherein a gate of the first transistor is coupled to the third node to receive the first signal, a source of the first transistor is coupled to the first node, and a drain of the first transistor is coupled to the second node;
a second transistor, wherein a source of the second transistor is coupled to the first node;
a third transistor, wherein a source of the third transistor is coupled to the second node, and wherein a gate of the second transistor is coupled to the second node and a gate of the third transistor is coupled to the first node; and
a fourth transistor, wherein a gate of the fourth transistor is coupled to the fourth node to receive the second signal, a source of the fourth transistor is coupled to the second node, and a drain of the fourth transistor is coupled to the first node.
